(19) United States
(12) Patent Application Publication
(10) Pub. No.: US 2015/0334855 A1
(43) Pub. Date: Nov. 19, 2015

(54) PROTECTIVE CASE FOR ELECTRONIC DEVICE AND METHOD FOR ACOUSTIC TRANSMISSION IN AIRTIGHT ENVIRONMENT

(71) Applicant: TE-YI CHU, NEW TAIPEI CITY (TW)

(72) Inventor: TE-YI CHU, NEW TAIPEI CITY (TW)

(21) Appl. No.: 14/277,922

(22) Filed: May 15, 2014

(51) Int. Cl. H05K 5/00; H05K 5/06

(52) U.S. Cl. CPC H05K 5/0086; H05K 5/061; H05K 5/069; H05K 5/0013

(57) ABSTRACT

A protective case for an electronic device and a method for acoustic transmission in airtight environment are disclosed. The protective case includes a case body defining a sealed accommodating space. The accommodating space is configured to receive the electronic device that has a screen and an audio generating section and/or an audio receiving section. The case body has a protective film disposed corresponding to the screen so that when the electronic device is received in the accommodating space, an air chamber is formed between the film and the electronic device. The protective film has a PET layer and a thickness of 0.05 mm to 0.25 mm. The film is spaced from the electronic device by an interval of substantially 0.25 mm. Thereby the protective film acts as a diaphragm for transmitting sound to the audio receiving section and/or for transmitting a sound generated by the audio generating section outside.

### BACKGROUND OF THE INVENTION

1. Technical Field

The present invention relates to a protective case for an electronic device and a method for acoustic transmission in airtight environment. More particularly, the protective case uses a protective film on its case body as a sound-transmitting diaphragm, and adopts well-designed parameters to allow the electronic device received in the airtight case body to remain excellent in sound receiving and to allow the sound generated from the electronic device to be clearly transmitted out of the case body as well.

2. Description of Related Art

For protecting electronic devices from dirt, scrapes or moisture that may cause damage, some prior-art devices have been introduced, such as the subject matter of China Patent No. 202652296U, titled “Waterproof Protective Case for Mobile Phone”, which primarily comprises a front cover and a back cover seal combined with each other, with a closed chamber formed therebetween to accommodate a mobile phone. The front case is provided with a sound outlet covered by a waterproof membrane that prevent water from entering the protective case while allowing sound to be transmitted outward by vibrating the waterproof membrane, so as to protect the mobile phone from dirt, scrapes or moisture.

However, when a mobile phone is wrapped in such a sealed protective case, the volume of the phone is unavoidably reduced and not fully passed outward. For addressing this problem, some solutions introduced including US Patent Publication No. 20130271902 titled “Waterproof Case”, which mainly has an air chamber defined between a phone and a protective film of the case, so that the phone's sound can be guided to the air chamber and then transmitted outward with less sound attenuation by using the protective film having a relatively large area as a diaphragm.

While the foregoing prior-art can somehow reduce sound attenuation, the effect is not significant, and at most audio frequencies its sound-receiving effect is far inferior as compared to that of the same phone when unshelled. Thus, there is a need for a further improved solution.

### SUMMARY OF THE INVENTION

Hence, for solving the problems about volume attenuation of electronic devices when wrapped by existing protective cases, the inventor of the present invention has made researches and thereby developed a novel protective case for an electronic device.

In one aspect of the present invention, the protective case comprises a case body, wherein the case body includes a first case member, a sealing member, and a second case member. The sealing member is sandwiched between the first case member and the second case member while the first case member and the second case member are combined together in a disassemblable manner, so that a sealed accommodating space is formed between the first and second case members. The accommodating space is configured to receive the electronic device therein. The electronic device has a screen and at least one of an audio generating section and an audio receiving section. The second case member comprises a protective film corresponding in position to the screen of the electronic device so that when the electronic device is received in the accommodating space, an air chamber is formed between the protective film and the electronic device, whereby the protective film acts as a diaphragm for transmitting an external sound to the audio receiving section or for transmitting a sound generated by the audio generating section out of the accommodating space. The protective film comprises a polyethylene terephthalate (PET) layer and has a thickness of 0.05 mm to 0.25 mm, and the protective film and the electronic device are spaced by an interval of substantially 0.25 mm.

Further, the second case member comprises an abutting portion such configured that when the electronic device is fitted in the case body, the electronic device abuts against the abutting portion to form the air chamber therebetween.

Further, the second case member has an opening defined by a peripheral wall along which an abutting portion is arranged, and the protective film is fitted with the abutting portion of the second case member to cover the opening.

Further, the second case member has an opening defined by a peripheral wall along which the abutting portion is arranged, and the protective film is fitted with the abutting portion of the second case member by a hot-press forming method to cover the opening.

Further, the abutting portion comprises a plurality of subsections arranged into a ring, and each of the subsections extends along the peripheral wall of the opening for a length of 2 mm to 5 mm.

Further, the first case member comprises an inner engaging portion, and the second case member has an outer engaging portion mounted with the inner engaging portion of the first case member.

Further, the sealing member has a ringlike structure formed with a flange, and the outer engaging portion of the second case body is provided with a groove for allowing the flange of the sealing member to be inlaid therein.

Further, the protective film has a plurality of raised particles facing the air chamber, the raised particles are arranged at intervals of 1 mm, and each of the raised particles has a diameter of 0.06 mm to 0.08 mm.

Further, the audio generating section and the audio receiving section are disposed at a lateral side of the electronic device, and the case body comprises a blocking portion formed in the accommodating space and corresponding in position to the lateral side of the electronic device, so that each of the audio generating section and the audio receiving section of the electronic device is spaced apart from the case body by a gap, the gap communicating with the air chamber.

Further, the electronic device has a first inclined portion extending between the lateral side and the screen of the electronic device, and the case body is correspondingly provided with a second inclined portion that faces the first inclined portion across the gap.

Further, the first case member and the second case member are made from a material selected from the group consisting of polyphenylene sulfide mixed with fiberglass and nylon mixed with fiberglass.

In another aspect of the present invention, a protective case for an electronic device that comprises a case body. The case body defines a sealed accommodating space therein, wherein the accommodating space is configured to receive the electronic device. The electronic device comprises a screen and at least one of an audio generating section and an audio receiving section. The case body comprises a protective film corresponding in position to the screen of the electronic device so that when the electronic device is received in the accommodating space, an air chamber is formed between the protective film and the electronic device, whereby the protective film acts as a diaphragm for transmitting an external sound to the audio receiving section or for transmitting a sound generated by the audio generating section out of the accommodating space. The protective film comprises a polyethylene terephthalate (PET) layer and has a thickness of 0.05 mm to 0.25 mm, and the protective film and the electronic device are spaced by an interval of substantially 0.25 mm.

The present invention further provides a method for acoustic transmission in an airtight environment, comprising the steps of:

providing a polyethylene terephthalate (PET) film when an audio generating section is located in an airtight accommodating space, wherein the film is spaced apart from the audio generating section by an interval of substantially 0.25 mm, and wherein the film has a thickness of 0.05 mm to 0.25 mm; and

making the film act as a diaphragm for transmitting a sound generated by the audio generating section located in the airtight accommodating space or by an sound source located outside the airtight accommodating space.

The present invention is beneficial for the features that:

1. The present invention implements the protective film of the case body as a sound-transmitting diaphragm, and adopts well-designed parameters to allow the electronic device received in the airtight case body to remain excellent in sound receiving and allow sound generated from the electronic device to be clearly transmitted out of the airtight case body, so is perfect to be applied to the speakerphone function of mobile phones.

2. The protective film according to the present invention is fitted to the second case member through hot-press molding. This on one hand allows the protective film to be combined with the second case member with enhanced combining strength and, on the other hand, allows the protective film to vibrate at higher frequency as a result of the relatively high tension caused by post-hot-molding shrinkage.

3. The protective film according to the present invention has plural raised particles that help to prevent creases or air bubbles from forming in or under the protective film.

### BRIEF DESCRIPTION OF THE DRAWINGS

The above and other objectives, features, and advantages of the present invention are hereunder illustrated with preferred embodiments in conjunction with the accompanying drawings.

FIG. 1 is a perspective view of one embodiment of the present invention receiving therein an electronic device.

FIG. 2 is an exploded view of the embodiment of the present invention.

FIG. 3 is a partially enlarged view of FIG. 2 according to the embodiment of the present invention.

FIG. 4 is a schematic cross-sectional view taken along line 4-4 of FIG. 1.

FIG. 5 illustrates how sound is transmitted outward from the case body according to the embodiment of the present invention.

FIG. 6 is a schematic, enlarged cross-sectional view taken along line 6-6 of FIG. 1 illustrating how external sound is transmitted into the case body according to the embodiment of the present invention.

FIG. 7 is a graph of data obtained from experiments where identical electronic devices are fitted into variations of the disclosed case bodies with different protective film thicknesses and unarmed with the case body, respectively, when they receive sound at various audio frequencies.

FIG. 8 is a graph of data obtained from experiments where identical electronic devices are fitted into variations of the disclosed case bodies with different protective film thicknesses and unarmed with the case body, respectively, when they generate sound at various audio frequencies.

### DETAILED DESCRIPTION OF THE INVENTION

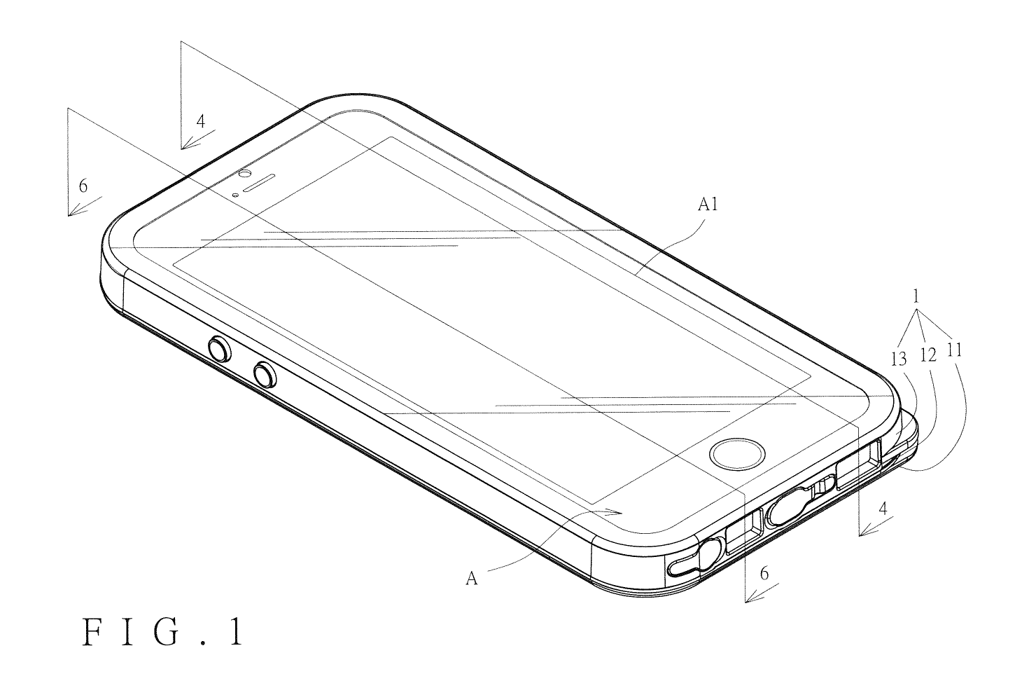

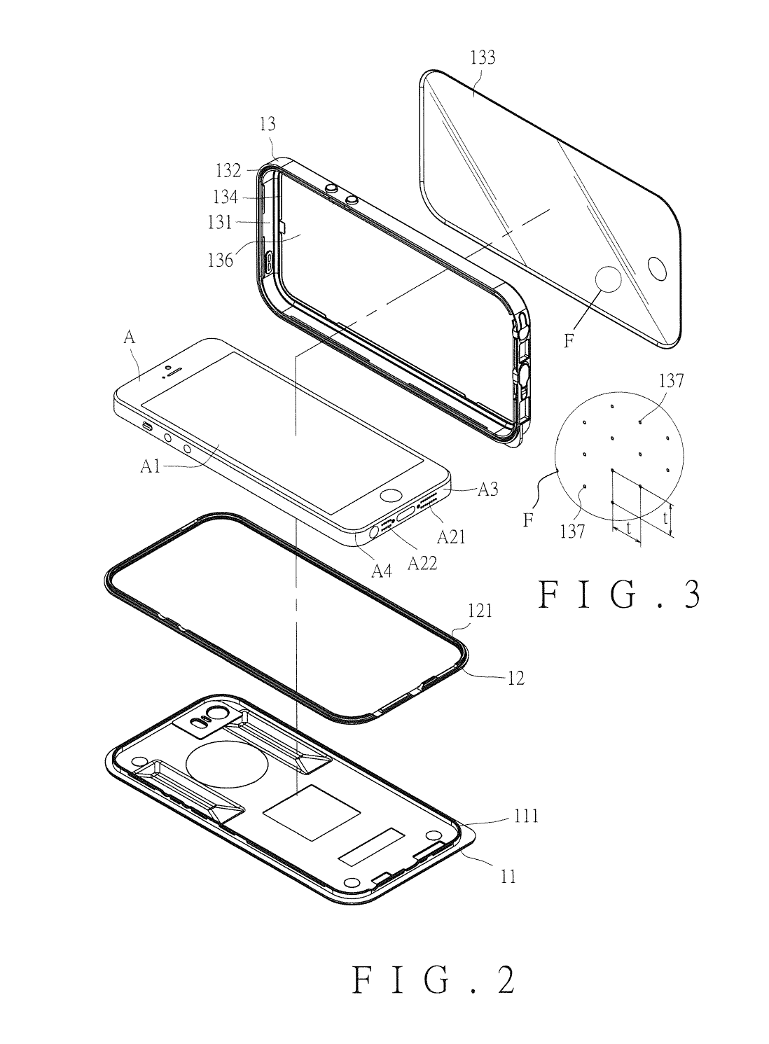

As shown in FIG. 1 and FIG. 2, a protective case according to an embodiment of the present invention is served to wrap an electronic device (A). The electronic device (A) has a screen (A1), an audio generating section (A21), and an audio receiving section (A22). The protective case comprises a case body (1).

The case body (1) comprises a first case member (11), a sealing member (12), and a second case member (13). The second case member (13) is combined with the first case member (11) so as to sandwich the sealing member (12) therebetween and thereby define an accommodating space (14) for receiving the electronic device (A).

Preferably, the first case member (11) and the second case member (13) are combined in a disassemblable manner. For example, the first case member (11) is provided with an inner engaging portion (111), and the second case member (13) is provided with an outer engaging portion (131) for engaging with the inner engaging portion (111); alternatively, the first case member (11) also can be removably mounted around the second case member (13), as long as the electronic device (A) can be easily fitted in the case body (1) for waterproofing, dustproofing, or dirtproofing, or for appearance change. Otherwise, the case body (1) can be formed as a housing of the electronic device (A) in another embodiment.

Preferably, the sealing member (12) has a ringlike structure that includes a flange (121), and the outer engaging portion (131) of the second case member (13) is provided with a groove (132) into which the flange (121) of the sealing member (12) is allowed to be inlaid for further improving the sealing effect.

In this embodiment, the material from which the first case member (11) and the second case member (13) are made can be polyphenylene sulfide (PPS) mixed with fiberglass or nylon mixed with fiberglass, so as to endow the case body (1) with both strength and lightness. Of course, other materials that have similar or equivalent rigidity and lightness can be alternatively used.

Referring to FIG. 4, the second case member (13) comprises a transparent protective film (133) corresponding in position to the screen (A1) of the electronic device (A). In addition, the second case member (13) has an abutting portion (134) which is such configured that when the electronic device (A) is fitted into the case body (1), the electronic device (A) can abut against the abutting portion (134) to form an air chamber (135) between the electronic device (A) and the abutting portion (134) of the second case memver (13).

The protective film (133) is substantially a layer of polyethylene terephthalate (PET), on which a hardened layer and a static layer can be selectively coated. The protective film (133) has a thickness of 0.05 mm to 0.25 mm, and preferably of 0.125 mm to 0.25 mm, with certain rigidity (e.g., having scratch resistance of 3 to 3.5 H pencil hardness). It is to be noted that a protective film which is too thin is adverse to the hardened-layer coating process and is likely to deform or crease under its hot-press forming process or under various use conditions (such as where it receives a water pressure), in turn adversely affecting vibrational capability of the protective film. More specifically, the second case member (13) includes an opening (136) defined by a peripheral wall, and the abutting portion (134) is arranged along the peripheral wall of the opening (136). The protective film (133) is fitted to the abutting portion (134) of the second case member (13) by hot-press forming method, such as by in-mold forming process, to cover the opening (136). This on the one hand allows the protective film (133) to be combined with the second case member (13) with enhanced combining strength and, on the other hand, allows the protective film (133) to vibrate at a higher frequency as a result of the relatively high tension thereof caused by post-hot-press-molding shrinkage.

It is to be noted that the abutting portion (134) has a thickness of about 0.25 mm to 0.3 mm, which is substantially 0.25 mm with a certain allowance, and is embodied as plural separated subsections arranged at intervals along the peripheral wall of the opening (136) as shown. In other embodiments, however, the abutting portion (134) may be in the form of a continuous flange, or spaced protrusions or bumps, as long as it is able to space the electronic device (A) from the protective film (133) by a distance and thus to define the air chamber (135). Preferably, each of the subsections has a length of 2 mm to 5 mm, so as to provide a sufficient contacting area to the electronic device (A) and thereby prevent the electronic device (A) from waggleing due to insufficient structural support.

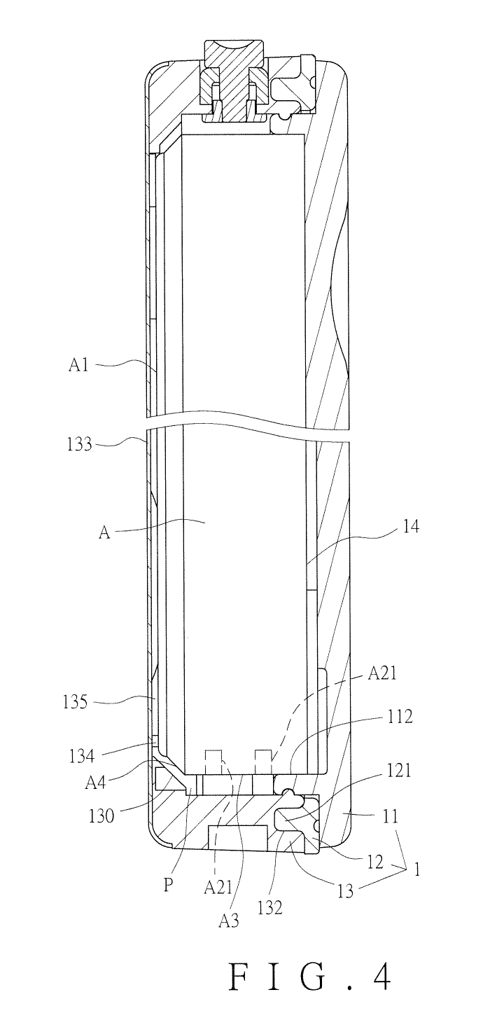

Also referring to FIG. 3, preferably, the protective film (133) has a plurality of raised particles (137) facing the air chamber (135), in order to prevent creases or air bubbles from forming in or under the protective film (133). More particularly, in the present embodiment, the raised particles (137) have a diameter of 0.06 mm to 0.08 mm, and any two adjacent said raised particles (137) are spaced by an interval (t) of 1 mm, in order to make the raised particles (137) less visible and less perceptible to people who view the screen of the electronic device (A) through the protective film (133).

In this embodiment, the audio generating section (A21) and the audio receiving section (A22) of the electronic device (A) is disposed on the lateral side (A3) which is substantially perpendicular to the surface having the screen (A1). Accordingly, the first case member (11) is provided with a blocking portion (112) for contacting the lateral side (A3) of the electronic device (A), so that the audio generating section (A21) and the audio receiving section (A22) of the electronic device (A) are spaced apart from the second case member (13) by a gap (P) which communicates with the air chamber (135). Moreover, the electronic device (A) has a first inclined portion (A4) extends between the lateral side (A3) and the screen (A1) thereof, and the second case member (13) of the case body (1) is correspondingly provided with a second inclined portion (130) that faces the first inclined portion (A4) across the gap (P). Preferably, the blocking portion (112) is formed at the inner side of the inner engaging portion (111) of the first case member (11), but in other embodiments, the blocking portion (112) may be disposed on the second case member (13), as long as the gap (P) is formed between the case body (1) and the lateral side (A3) of the electronic device (A).

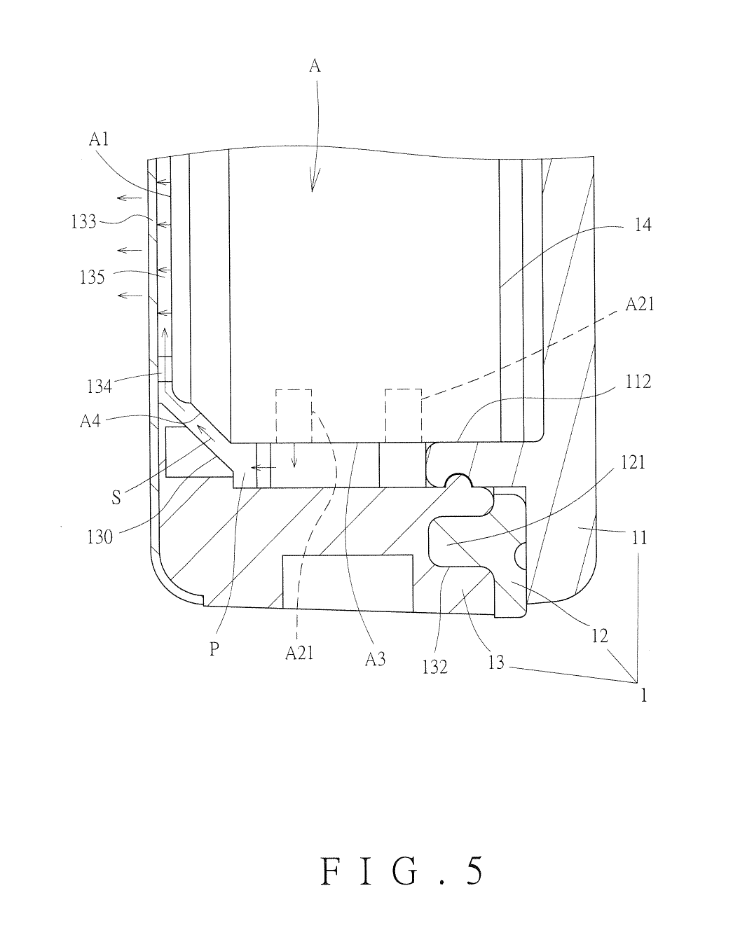

FIG. 5 illustrates how the sound (S) generated by the electronic device (A) is transmitted outward through the case body (1). Firstly, due to the abutting portion (134) formed on the second case member (13) for abutting against the surface of the electronic device (A) having the screen (A1) as well as due to the blocking portion (112) for contacting the lateral side (A3) of the electronic device (A), the gap (P) that spaces the second inclined portion (130) of the case body (1) from the first inclined portion (A4) of the electronic device (A) is communicated with the air chamber (135) when the electronic device (A) is fitted into the case body (1).

Therefore, when the electronic device (A) generates the sound (S) by its audio generating section (A21), the sound (S) enters the air chamber (135) through the gap (P) to vibrate the protective film (133) and then is transmitted out of the case body (1). Thanks to the well-designed geometric parameter of the protective film (133) and the clearance left between the case body (1) and the electronic device (A), the possible attenuation of the sound (S) is minimized and it is even expectable that the sound (S) is amplified, so the protective case provides solid acoustical benefits.

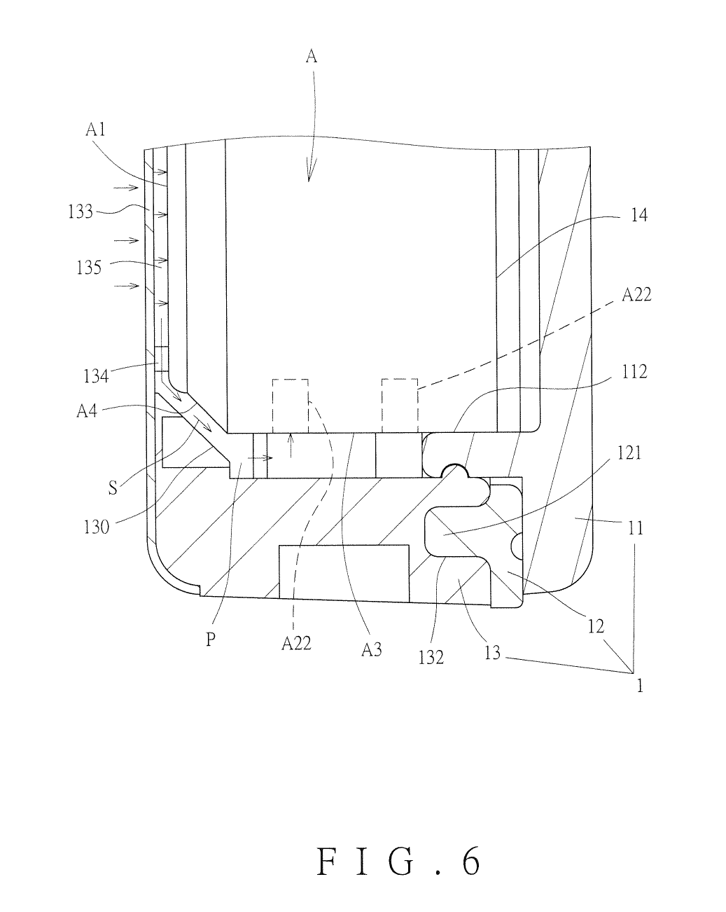

FIG. 6 illustrates how the electronic device (A) receives external sound through the case body (1). For sound generated outside the accommodating space (14) of the case body (1), the protective film (133) also acts as a diaphragm that transmits the sound, so that the waves of the sound enter the gap (P) through the air chamber (135), and then are received by the audio receiving section (A22) of the electronic device (A). The way that the sound gets received contributes to minimized sound attenuation and even amplified sound volume, making the protective case have acoustical benefits in addition to its protective function.

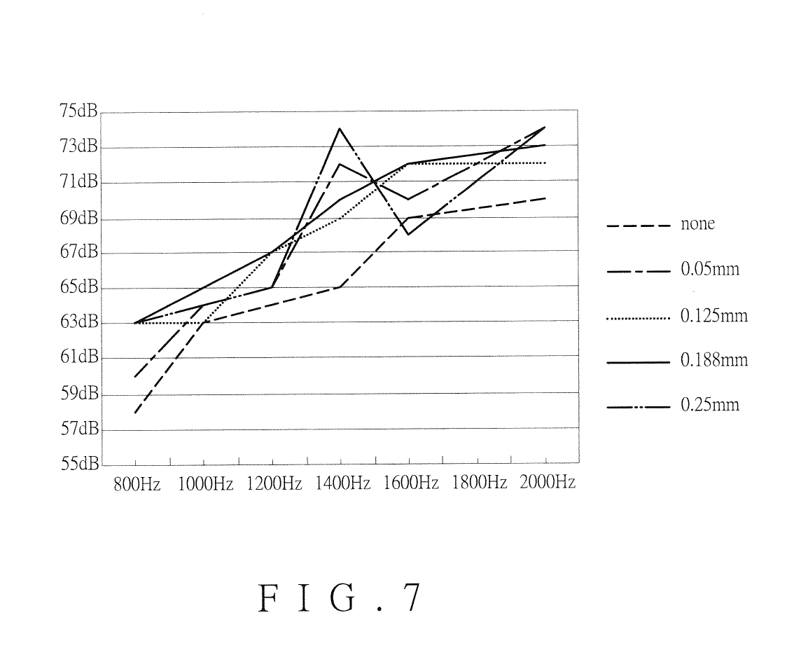

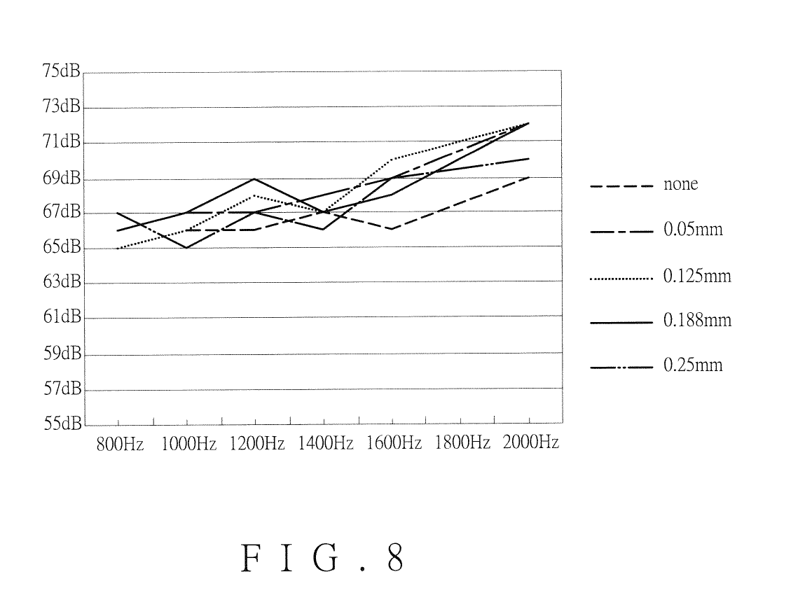

FIG. 7 graphs the data obtained from experiments in which the electronic device (A) is fitted into variation of case bodies with different protective-film thickness, and sound intensities, with respect to various audio frequencies, received by the electronic device (A) are measured. FIG. 8 graphs the data obtained from experiments in which the electronic device (A) is fitted into variation of case bodies with different protective-film thickness, and sound intentisities, with respect to different audio frequencies, transmitted out of the case body (1) are measured. As shown in both FIGS. 7 and 8, when the electronic device (A) is fitted into the case body (1) with the protective film (133) of 0.05 mm to 0.25 mm thick, the sound intensities are mostly superior to those measured without the case body (1). Specifically, the measured sound intensities are slightly inferior to those measured without the case body (1) only when the electronic device (A) is fitted into the case body (1) with the protective film (133) of 0.25 mm thick.

The sound intensites, with respect to various audio frequencies, received by the electronic device (A) when the electronic device (A) is unshelled and shelled in the case body (1) with the protective films of different thicknesses are respectively provided in TABLE 1.

TABLE 1

| | | | | 1400 | 1600 | 2000 |
|---|---|---|---|---|---|---|
| | 800 Hz | 1000 Hz | 1200 Hz | Hz | Hz | Hz |
| None | 58 dB | 63 dB | 64 dB | 65 dB | 69 dB | 70 dB |
| 0.05 mm | 60 dB | 64 dB | 65 dB | 72 dB | 70 dB | 74 dB |
| 0.125 mm | 63 dB | 63 dB | 67 dB | 69 dB | 72 dB | 72 dB |
| 0.188 mm | 63 dB | 65 dB | 67 dB | 70 dB | 72 dB | 73 dB |
| 0.25 mm | 63 dB | 64 dB | 65 dB | 74 dB | 68 dB | 74 dB |

The sound intensites, with respect to various audio frequencies, transmitted outward when the electronic device (A) is unshelled and shelled in the case body (1) with the protective films of different thicknesses are respectively provided in TABLE 2.

TABLE 2

| | | | | 1400 | 1600 | 2000 |
|---|---|---|---|---|---|---|
| | 800 Hz | 1000 Hz | 1200 Hz | Hz | Hz | Hz |
| none | 65 dB | 66 dB | 66 dB | 67 dB | 66 dB | 69 dB |
| 0.05 mm | 66 dB | 67 dB | 67 dB | 68 dB | 69 dB | 72 dB |
| 0.125 mm | 65 dB | 66 dB | 68 dB | 67 dB | 70 dB | 72 dB |
| 0.188 mm | 66 dB | 67 dB | 69 dB | 67 dB | 68 dB | 71 dB |
| 0.25 mm | 67 dB | 65 dB | 67 dB | 66 dB | 69 dB | 70 dB |

The material properties of the 0.125 mm thick protective film are provided in TABLE 3.

TABLE 3

| Item | | Testing Method | Unit | Value |
|---|---|---|---|---|
| Tensile Strength at Break | MD | ASTM D882 | MPa | 196 |
| | TD | ASTM D882 | MPa | 206 |
| Elongation at Break | MD | ASTM D882 | % | 120 |
| | TD | ASTM D882 | % | 100 |
| Thermal Shrinkage | MD | 150° C., 30 minutes | % | 1 |
| | TD | 150° C., 30 minutes | % | 0.4 |

The material properties of the 0.188 mm thick protective film are provided in TABLE 4.

TABLE 4

| Item | | Testing Method | Unit | Value |
|---|---|---|---|---|
| Tensile Strength at Break | MD | ASTM D882 | Kg/mm² | 18 |
| | TD | ASTM D882 | Kg/mm² | 22 |
| Elongation at Break | MD | ASTM D882 | % | 200 |
| | TD | ASTM D882 | % | 110 |
| Thermal Shrinkage | MD | 150° C., 30 minutes | % | 0.8 |
| | TD | 150° C., 30 minutes | % | 0.4 |

The present invention has been described with reference to the preferred embodiments and it is understood that the embodiments are not intended to limit the scope of the present invention. Moreover, as the contents disclosed herein should be readily understood and can be implemented by a person skilled in the art, all equivalent changes or modifications which do not depart from the concept of the present invention should be encompassed by the appended claims.

What is claimed is:

1. A protective case for an electronic device, the protective case having a case body; wherein the case body includes a first case member, a sealing member, and a second case member; the sealing member is sandwiched between the first case member and the second case member while the first case member and the second case member are combined together in a disassemblable manner, so that a sealed accommodating space is formed between the first and second case members; the accommodating space is configured to receive the electronic device therein; the electronic device has a screen and at least one of an audio generating section and an audio receiving section; the second case member comprises a protective film corresponding in position to the screen of the electronic device so that when the electronic device is received in the accommodating space, an air chamber is formed between the protective film and the electronic device, whereby the protective film acts as a diaphragm for transmitting an external sound to the audio receiving section or for transmitting a sound generated by the audio generating section out of the accommodating space; and wherein the protective case is characterized in that:
the protective film comprises a polyethylene terephthalate (PET) layer and has a thickness of 0.05 mm to 0.25 mm; and the protective film and the electronic device are spaced by an interval of substantially 0.25 mm.

2. The protective case of claim 1, wherein the second case member comprises an abutting portion such configured that when the electronic device is fitted in the case body, the electronic device abuts against the abutting portion to form the air chamber therebetween.

3. The protective case of claim 1, wherein the second case member has an opening defined by a peripheral wall along which an abutting portion is arranged, and the protective film is fitted with the abutting portion of the second case member to cover the opening.

4. The protective case of claim 2, wherein the second case member has an opening defined by a peripheral wall along which the abutting portion is arranged, and the protective film is fitted with the abutting portion of the second case member by a hot-press forming method to cover the opening.

5. The protective case of claim 4, wherein the abutting portion comprises a plurality of subsections arranged into a ring, and each of the subsections extends along the peripheral wall of the opening for a length of 2 mm to 5 mm.

6. The protective case of claim 1, wherein the first case member has an inner engaging portion, and the second case member has an outer engaging portion mounted with the inner engaging portion of the first case member.

7. The protective case of claim 6, wherein the sealing member has a ringlike structure formed with a flange, and the outer engaging portion of the second case body is provided with a groove for allowing the flange of the sealing member to be inlaid therein.

8. The protective case of claim 1, wherein the protective film has a plurality of raised particles facing the air chamber, the raised particles are arranged at intervals of 1 mm, and each of the raised particles has a diameter of 0.06 mm to 0.08 mm.

9. The protective case of claim 1, wherein the audio generating section and the audio receiving section are disposed at a lateral side of the electronic device, and the case body comprises a blocking portion formed in the accommodating space and corresponding in position to the lateral side of the electronic device, so that each of the audio generating section and the audio receiving section of the electronic device is spaced apart from the case body by a gap, the gap communicating with the air chamber.

10. The protective case of claim 9, wherein the electronic device has a first inclined portion extending between the lateral side and the screen of the electronic device, and the case body is correspondingly provided with a second inclined portion that faces the first inclined portion across the gap.

11. The protective case of claim 1, wherein the first case member and the second case member are made from a material selected from the group consisting of polyphenylene sulfide mixed with fiberglass and nylon mixed with fiberglass.

12. A protective case for an electronic device, the protective case comprising a case body which defines a sealed accommodating space therein, wherein the accommodating space is configured to receive the electronic device; the electronic device comprises a screen and at least one of an audio generating section and an audio receiving section; the case body comprises a protective film corresponding in position to the screen of the electronic device so that when the electronic device is received in the accommodating space, an air chamber is formed between the protective film and the electronic device, whereby the protective film acts as a diaphragm for transmitting an external sound to the audio receiving section or for transmitting a sound generated by the audio generating section out of the accommodating space; and wherein the protective case is characterized in that:
the protective film comprises a polyethylene terephthalate (PET) layer and has a thickness of 0.05 mm to 0.25 mm; and the protective film and the electronic device are spaced by an interval of substantially 0.25 mm.

13. A method for acoustic transmission in an airtight environment, comprising the steps of:
providing a polyethylene terephthalate (PET) film when an audio generating section is located in an airtight accommodating space, wherein the film is spaced apart from the audio generating section by an interval of substantially 0.25 mm, and wherein the film has a thickness of 0.05 mm to 0.25 mm; and
making the film act as a diaphragm for transmitting a sound generated by the audio generating section located in the airtight accommodating space or by an sound source located outside the airtight accommodating space.
